(19) United States
(12) Patent Application Publication
(10) Pub. No.: US 2024/0399875 A1
(43) Pub. Date: Dec. 5, 2024

(54) Protective Device for a High-Voltage Battery in Electrified Motor Vehicles

(71) Applicant: Bayerische Motoren Werke Aktiengesellschaft, Muenchen (DE)

(72) Inventors: Franz SCHWINGHAMMER, Muenchen (DE); Lukas WOLF, Muenchen (DE)

(21) Appl. No.: 18/697,538

(22) PCT Filed: Nov. 17, 2022
(86) PCT No.: PCT/EP2022/082178

§ 371 Date: Apr. 1, 2024

(30) Foreign Application Priority Data
Dec. 21, 2021 (DE) 10 2021 133 976.6

(51) Int. Cl. B60L 3/00; B60L 58/16

(52) U.S. Cl. CPC B60L 3/0046; B60L 58/16; B60L 2250/16

(57) ABSTRACT

A protective device according to forms of the present disclosure for a high-voltage battery in an electrified motor vehicle is equipped with a display and with an electronic control unit which is configured to determine a first predicted state of health of the high-voltage battery and a second predicted state of health of the high-voltage battery on the basis of defined parameters and to output these states in the form of two separate display areas on the display. The first predicted state of health is determined on the basis of the past usage behavior. The second predicted state of health is determined on the basis of the assumption that at least one specified usage recommendation is followed in the future.

### BACKGROUND AND SUMMARY

The invention relates to a protective device for a high-voltage battery in electrified motor vehicles which takes measures against excessive aging.

A protective device of this type is described, for example, in DE 10 2021 127 371 from the applicant, which is not a prior publication.

In electrified motor vehicles (for example hybrid vehicles or pure electric vehicles), use is predominantly made of lithium-ion batteries as rechargeable traction batteries, which are subject to physical aging. A distinction is made between calendrical and cyclic aging, wherein the calendrical aging is greater, for example, the higher the state of charge in storage and the temperature of the rechargeable traction battery.

Rechargeable traction batteries as electrical energy sources for driving electrified motor vehicles are often also referred to as high-voltage batteries or high-voltage storage devices.

High-voltage storage devices are usually fully charged where possible, provided a charging cable is plugged in and the vehicle user has set a state of charge of 100% as the charging target. According to the prior art, full charging is generally carried out without the intelligent prediction of when the vehicle is expected to be started up again, except when a manual input device makes it possible for the user to program the specific time for starting up again. If an electric vehicle remains plugged in for a relatively long time and is not moved, the battery ages to an unnecessarily significant degree, in particular in the case of an absence for several weeks (vacation, business trip, etc.), for example. This is just one example of user behavior that has an effect on the aging of a high-voltage battery.

It is already generally known, in principle, for example, that the battery ages to a significantly lower degree at a state of charge of at most approximately 80%.

One possible method for determining a state of health of a lithium-ion battery based on aging characteristic variables is known, for example, from DE 10 2019 125 375 A1. This method comprises recording a historic load profile of the battery and, based on this, identifying an anticipated load profile, from which a future aging value is predicted. Several aging values can be determined based on different anticipated load profiles. How this method is intended to be used to reduce the aging remains open.

It is the object of the invention to further reduce the aging of a battery in a simple and reliable manner in order to avoid having to change the batteries early for reasons of increased sustainability and reduced costs.

This object is addressed by the features of patent claim 8. Further advantageous refinements of the invention are the subject matter of the dependent claims.

A protective device according to the invention for a high-voltage battery in an electrified motor vehicle is provided with a display screen and with an electronic control unit which is configured in such a way that it determines a first predicted state of health of the high-voltage battery and a second predicted state of health of the high-voltage battery on the basis of defined parameters and outputs these states in the form of two separate display areas on the display. The first predicted state of health is determined on the basis of the past usage behavior. The second predicted state of health is determined on the basis of the assumption that at least one specified usage recommendation (preferably all specified usage recommendations) is (are) followed in the future.

In one form of the invention, the at least one usage recommendation can be displayed on the display screen at the same time as the displaying of the second predicted state of health. The at least one usage recommendation may be a respective recommendation selected in a time-controlled or event-controlled manner from a plurality of defined usage recommendations stored in the control unit.

Furthermore, the determination of the two predicted states of health is based on a defined period of time, for example on the entire assumed vehicle service life (for example a particular number of years) or on the warranty period of the high-voltage battery or on a time frame that can be selected by the user or on a date that can be input.

The display of the second predicted state of health is preferably able to be displayed on the display screen according to an event rule during travel or at a standstill in connection with a particular usage recommendation which is to be output presently and which is selected in a time-controlled or event-controlled manner by the control unit. An event may be, for example, an assumed, shortly upcoming start of a charging process in connection with the previous behavior of the user to always fully charge. If the presence of this exemplary event is identified by the control unit, according to the invention firstly the displaying of the second predicted state of health is activated and preferably secondly the usage recommendation that is most effective in this regard is output at the same time, namely the recommendation to set the target state of charge to 80%.

The at least one usage recommendation (the respectively most effective depending on the event) is displayed to the vehicle user to relieve the strain on them only when following the recommendation leads to an improved prediction. Therefore, only usage recommendations that have not yet been taken into account or that have not been taken into account enough in the previous usage behavior are output. The invention is based on the following considerations:

The invention relates to a protective device for a high-voltage battery in an electrified motor vehicle, in particular to a protective device for reducing aging of high-voltage storage devices using aging prediction. The state of health is also referred to as “SOH” for short. According to the invention, a separate SOH prediction is created, which allows for behavior that will protect the battery more in the future. According to forms of the invention, the user of the vehicle is preferably provided with both advice (usage recommendations) for improved behavior and a display of the SOH prediction is output on a user display screen, which takes the following of this advice as a starting point. In this case, the displaying of a first SOH prediction which takes the continuation of the previous behavior as a starting point is in contrast with the second SOH prediction which takes an improved behavior according to the pieces of advice as a starting point.

By way of example, different areas of a scale are demarcated from one another in terms of color in order to show the extent of the aging.

Until now, the vehicle user has generally not yet been shown the state of health (SOH) of a rechargeable traction battery or a high-voltage storage device in an electrified vehicle directly. In the future, however, this may be required by law.

Although rechargeable traction batteries or high-voltage storage devices in the form of lithium-ion batteries age physically, the vehicle user can influence the extent of the aging by way of their usage behavior. This aging cannot be eliminated but can be reduced by way of the user behavior.

The prior art is that there are basic possibilities for users of electric vehicles to take certain measures or implement certain settings. These possibilities include, inter alia:
freely accessible information about the battery aging (for example do not park an electric vehicle in the sun)
setting options in the vehicle (for example set the charging target to <80%)
displaying when there is a risk of exhaustive discharge in the vehicle

Disadvantages of the prior art are at least the following:
the user receives only basic information about the recommended use. A future prediction of the aging of the HVS and thus the high degree of efficiency of the recommended measures based on historic use is not available.
the user does not receive any feedback about their previous usage behavior. It is therefore not possible to adapt the user behavior meaningfully in order to minimize the aging of the HVS.
the battery may have to be replaced earlier, which reduces the positive environmental protection effect (sustainability) of electric vehicles.
the tendency to exchange batteries earlier leads to increased costs.

Forms of the invention comprise the following basic principle:

The invention proposes presenting the state of health (SOH) of a high-voltage storage device (HVS) in at least two separate displays (first “SOH-prediction-old” and second “SOH-prediction-new”). A third display may also be provided, which respectively shows the current state of health (“SOH history”).

The invention provides the vehicle user with the possibility of reflecting on their previous charging and driving behavior, based on specific, defined and preferably interactive usage recommendations, and to improve this for the future if necessary.

The invention results in the following advantages:
the vehicle user can reflect on their previous usage behavior and adapt their future usage behavior to the usage recommendations.
the battery does not age as severely and does not have to be replaced as quickly (product longevity).
this promotes sustainable and resource-protecting use and prevents repair costs.

### BRIEF DESCRIPTION OF THE DRAWINGS

The drawings illustrate an exemplary embodiment of the invention.

FIG. 1 shows an exemplary embodiment of SOH displays providing information based on SOH history and based on a prediction depending on future behavior and

FIG. 2 shows a schematic illustration of components of one form of a protective device according to the invention.

### DETAILED DESCRIPTION OF THE DRAWINGS

The following text describes a display for presenting a state of health, SOH for short.

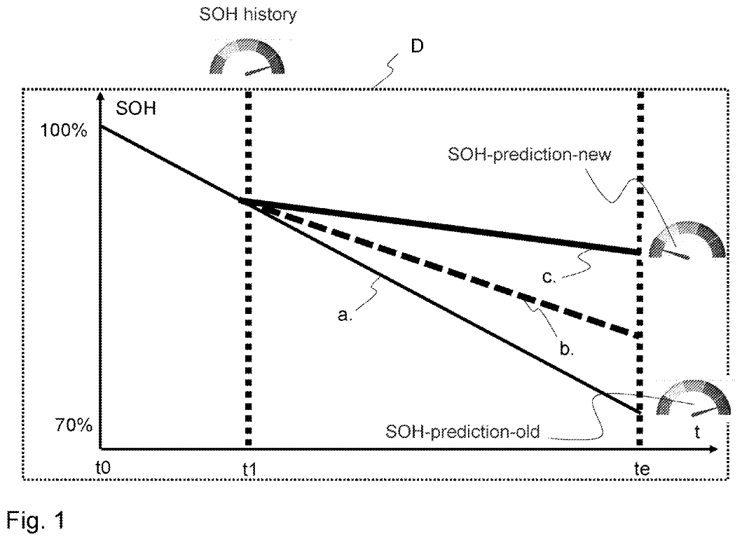

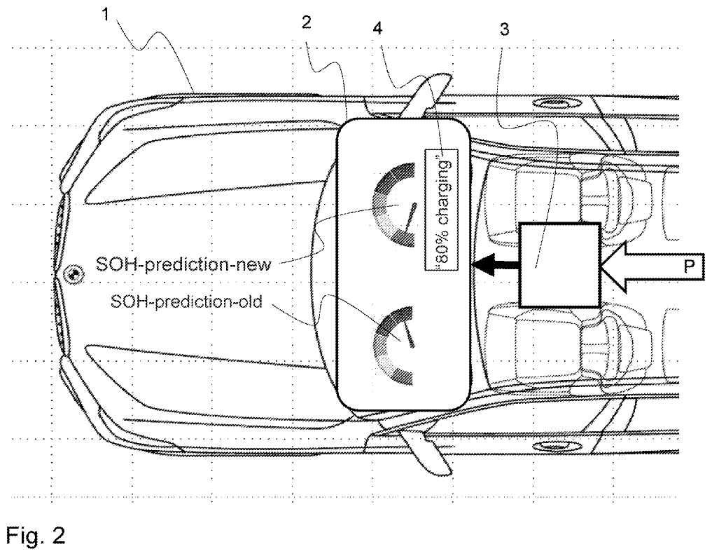

FIG. 1 is used as a basis for describing an exemplary embodiment of three SOH displays, namely a display of a historic state of health “SOH history” at the current time t1, a first predicting display “SOH-prediction-old” and a second predicting display “SOH-prediction-new”. The second predicting display “SOH-prediction-new” is dependent on the future following of (in this case, for example, all) recommended usage recommendations 4 (FIG. 2) relating to battery-protecting usage behavior. The SOH prediction without usage recommendations being followed while retaining the previous usage behavior of the improved SOH prediction taking into account at least one and preferably all usage recommendations is contrasted with the first predicting display “SOH-prediction-old”. The usage recommendation(s) is (are) preferably able to be selected and output in a time-controlled or event-controlled manner automatically to the current usage behavior as required, as described above.

The activation of the SOH displays on a display screen 2 of an electrified vehicle 1 is achieved through a corresponding configuration (in particular programming such as, in one example, instruction stored in a computer-readable storage medium) of an electronic control unit 3 (see FIG. 2).

The SOH displays can be embodied, for example, by means of a digital indicator on an, in this case round, scale—as illustrated here in FIG. 1. A bar-like scale would also be possible.

The two SOH prediction displays “SOH-prediction-old” and “SOH-prediction-new” each preferably relates to a defined period of time te, for example the end of an assumed lifespan (for example 8 years).

The display “SOH-prediction-new” is activated based on a possible future improved usage behavior (charging/driving) from a current time t1.

At least this second SOH prediction display “SOH-prediction-new” can be activated in accordance with a time rule or event rule stored in the control unit 3. An event rule would be, for example, the identification of a currently useful usage recommendation 4 (FIG. 2).

At least one usage recommendation 4 for reducing aging, for example the recommendation previously considered the least in the history or the most effective recommendation, is preferably proposed at the same time as the second display “SOH-prediction-new”.

All of the SOH states displayed can each be displayed, for example, using three (for example green=>yellow=>red) to five scale ranges with different colors (for example in this case from left to right: five grey steps or green=>yellow=>orange=>light red=>dark red).

An exemplary classification in an example of a scale with three scale ranges:

Green: the user considered the usage recommendations and the HV storage device has aged only a little and better than average. For example, the car is/has been regularly charged to only an 80% state of charge, rapid charging not used often, parked at moderate ambient temperatures, and moved at average driving speeds consistently with a low degree of consumption.

Yellow: the user considered the usage recommendations sporadically and the HV storage device has aged somewhat and is average. For example, the car is/has been charged more often to a 100% state of charge, rapid charging used more often, sometimes parked at higher ambient temperatures, and moved at high driving speeds more often in a sporty manner.

Red: the user seldom considered the usage recommendations and the HV storage device has aged to a more significant degree and is below average. For example, the car is/has been almost always charged to a 100% state of charge, rapid charging used almost always, often parked at higher ambient temperatures, and often moved at very high driving speed in a very sporty manner.

The display of the second predicted state of health SOH-prediction-new is thus output under the premise that the usage recommendations (charging/driving) are taken into account in the future.

The second predicted state of health SOH-prediction-new can be displayed in the same way as the first SOH display, that is to say, for example, by means of the aforementioned scale. As an alternative or in addition, it can be displayed in a graph corresponding to or similar to the graph D illustrated in FIG. 1.

With respect to the displays of the SOH predictions in the form of a graph, the protective device according to the invention may preferably offer and perform, selectively or overall, the following options, which can be selected via a menu on the display screen (for example preferably designed as an input and output unit):
displaying the SOH-prediction-old based on the entire previous historical usage behavior (charging/driving) extrapolated over the entire defined period of time te.
displaying the SOH prediction based on the previous historical usage behavior (charging/driving) over a defined shorter time than the entire defined period of time te (for example the last 1000 km or three weeks or 15 charging processes).
displaying the SOH-prediction-new based on the assumption that the user or driver follows the output usage recommendation(s) (for example “charging target max. 80%” and “less DC charging”) on an ongoing basis in the future.

Further possible usage recommendations 4 that can be predetermined at least analogously and also selected individually are listed below in table 1 by way of example, these usage recommendations being able to be output automatically in a time-controlled or event-controlled manner as required depending on the defined parameters for determining the state of health SOH together with the SOH display “SOH-prediction-new” of the second predicted state of health of the high-voltage battery:

### Table 1:

(1) In the case of long-distance journeys, breaks (for example from about 15 minutes) increase the lifespan of the high-voltage energy store.
(2) The avoidance of high driving and charging powers, in particular shortly after the start of driving and charging and in the case of low ambient temperatures, increases the lifespan of the high-voltage storage device.
(3) A steady driving mode, for example using cruise control, with lower driving dynamics protects the lifespan of the high-voltage storage device.
(4) Timely charging before reaching states of charge of less than 10% and low charging strokes increase the lifespan of the high-voltage storage device.
(5) At states of charge of greater than 50% and sufficient remaining range for the next journey, it is not recommended to charge the storage device until after this journey.
(6) Infrequent full-charging is beneficial for the lifespan of the high-voltage storage device. A sensible charging target for covering typical routes is approximately 80%.
(7) The optimum state of charge in the case of relatively long standing times of an electric vehicle, for example due to a vacation, is between 30% and 50%.
(8) The optimum temperature for parking an electric vehicle is approximately between 10 and 15° C. The avoidance of high temperatures, for example due to direct sunlight, improves the lifespan.

Examples of defined parameters P for determining the state of health are the number of full-charging processes, accelerator pedal actuation, the usual external temperature when parked, the break times in the case of long-distance journeys, the number of rapid-charging processes and/or the power requirement by way of the driver demand.

The driver can therefore decide for themselves how they drive the car in the future as necessary.

The inventive “configuration” of the electronic control unit is preferably realized by way of a correspondingly programmed functional module in the form of a computer program product (software module).

1-7. (canceled)

8. A protective device for a high-voltage battery in an electrified motor vehicle, comprising:
a display screen; and
an electronic control unit configured to:
determine a first predicted state of health of a high-voltage battery and a second predicted state of health of the high-voltage battery on the basis of defined parameters; and
output the first predicted state of health and the second predicted state of health in the form of two separate displays on the display screen,
wherein the first predicted state of health is determined on the basis of past usage behavior and the second predicted state of health is determined on the basis of an assumption that at least one specified usage recommendation is followed in the future.

9. The protective device according to claim 8, wherein the electronic control unit is configured to display at least one usage recommendation on the display screen at the same time as displaying the second predicted state of health on the display screen.

10. The protective device according to claim 8, wherein the determination of the first predicted state of health and the determination of the second predicted state of heath are based on a defined period of time.

11. The protective device according to claim 8, wherein the electronic control unit is configured to display second predicted state of health on the display screen according to an event rule in connection with a particular usage recommendation which is presently output.

12. The protective device according to claim 8, wherein the electronic control unit is configured to output a usage recommendation only if it leads to an improved second state of health.

13. A vehicle comprising:
a protective device for a high-voltage battery in an electrified motor vehicle, comprising:
a display screen; and
an electronic control unit configured to:
determine a first predicted state of health of a high-voltage battery and a second predicted state of health of the high-voltage battery on the basis of defined parameters; and
output the first predicted state of health and the second predicted state of health in the form of two separate displays on the display screen,
wherein the first predicted state of health is determined on the basis of past usage behavior and the second predicted state of health is determined on the basis of an assumption that at least one specified usage recommendation is followed in the future.

14. A computer readable storage medium comprising a set of set of instructions that when executed by a control unit, cause the control unit to:
determine a first predicted state of health of a high-voltage battery and a second predicted state of health of the high-voltage battery on the basis of defined parameters; and
output on a display screen the first predicted state of health and the second predicted state of health in the form of two separate displays on the display screen,
wherein the first predicted state of health is determined on the basis of past usage behavior and the second predicted state of health is determined on the basis of an assumption that at least one specified usage recommendation is followed in the future.
